(19) United States
(12) Patent Application Publication
(10) Pub. No.: US 2023/0180422 A1
(43) Pub. Date: Jun. 8, 2023

(54) MODULAR WIND TURBINE AND DATA CENTER SYSTEM

(71) Applicant: EcoEdge Data, New York, NY (US)

(72) Inventor: Mehonaz Queeny Kazi, Brooklyn, NY (US)

(21) Appl. No.: 18/076,209

(22) Filed: Dec. 6, 2022

Related U.S. Application Data
(60) Provisional application No. 63/286,407, filed on Dec. 6, 2021.

(51) Int. Cl. H05K 7/14; F03D 80/80; H05K 7/20; G06F 1/20

(52) U.S. Cl. CPC H05K 7/1492; F03D 80/82; H05K 7/20736; G06F 1/206

(57) ABSTRACT

A modular system for a small-scale data center may be manufactured offsite and assembled within the housing of a wind turbine. The modular configuration allows for more rapid design, construction, and operation of the system for turnkey projects. The modular system employs optimized features to take advantage of wind turbine power and is structured for effective cooling. The modular data center system also has connectivity for maintenance oversight, remote management, communication between multiple modular wind turbine and data center systems, and power backup to ensure consistent operation as needed.

### CROSS-REFERENCE TO RELATED APPLICATIONS

The present patent application claims the priority benefit of U.S. provisional patent application No. 63/286,407 filed Dec. 6, 2021, the disclosure of which is incorporated by reference herein.

### BACKGROUND OF THE INVENTION

### 1. Field of the Invention

The present disclosure is generally related to systems for managing renewable energy, energy conservation and reuse, and associated modular infrastructure.

### 2. Description of the Related Art

Data centers are generally energy- and capital-intensive. Meanwhile, the growing demand for data and data-intensive services has therefore resulted in the proliferation of such data centers. The corresponding resource requirements for building, operating, and maintaining data centers has likewise increased dramatically.

There is, therefore, a need in the art for improved systems and methods of providing scalable digital infrastructures for assembling and operating data centers while reducing environmental impact.

### DESCRIPTIONS OF THE DRAWINGS

FIG. 1 illustrates an exemplary network environment in which a modular wind turbine and data center may be implemented.

FIGS. 2A-B illustrates exemplary configurations of a modular server unit.

FIGS. 3A-D illustrates exemplary configurations of a modular data center.

FIG. 4 is a flowchart illustrating an exemplary method of assembling modular data centers.

FIG. 5 is a flowchart illustrating an exemplary method of operating modular data centers.

FIG. 6 is a block diagram of an exemplary computing device that may be used to implement an embodiment of the present invention.

### DETAILED DESCRIPTION

Embodiments of the present disclosure integrate data storage and renewable energy by combining edge data centers with on-site wind energy, for example, for effective adaptive reuse. For multiple reasons, housing a data center within a wind turbine is beneficial. Doing so expands the utility of the real estate of the wind turbine, provides an adaptive reuse function, and reduces the embodied carbon of the data center, by not requiring an enclosure to be built for the data center. Locating the energy demand at the source of the energy supply reduces the cost of transmission (and losses associated with transmission over distance). Because wind turbines tend to be located in more remote geographies, there is a natural and inherent increase in security of the data center. In addition, the natural form of the tower of the wind turbine passively aids in the cooling process, thereby reducing the load on the cooling system.

Modularity of systems (wind turbine and data center) allow for interconnection through a networking system, which further provides for scalability. As more data capacity is needed, additional modular systems can be added and connected to existing configurations. The configuration of a modular data center further allows for improved ease of transport, installation, reconfiguration, and decommissioning. Modularity further provides for cooling optimization and maximization of available interior space. For example, a configuration may include long-lived infrastructure, such as cooling equipment, that is typically located at the base of the wind turbine while other equipment may be higher-up. Data capacity (e.g., racks with servers/mining equipment/storage) would be installed above the base in a modular configuration as shown in the diagram.) This allows for future expansion.

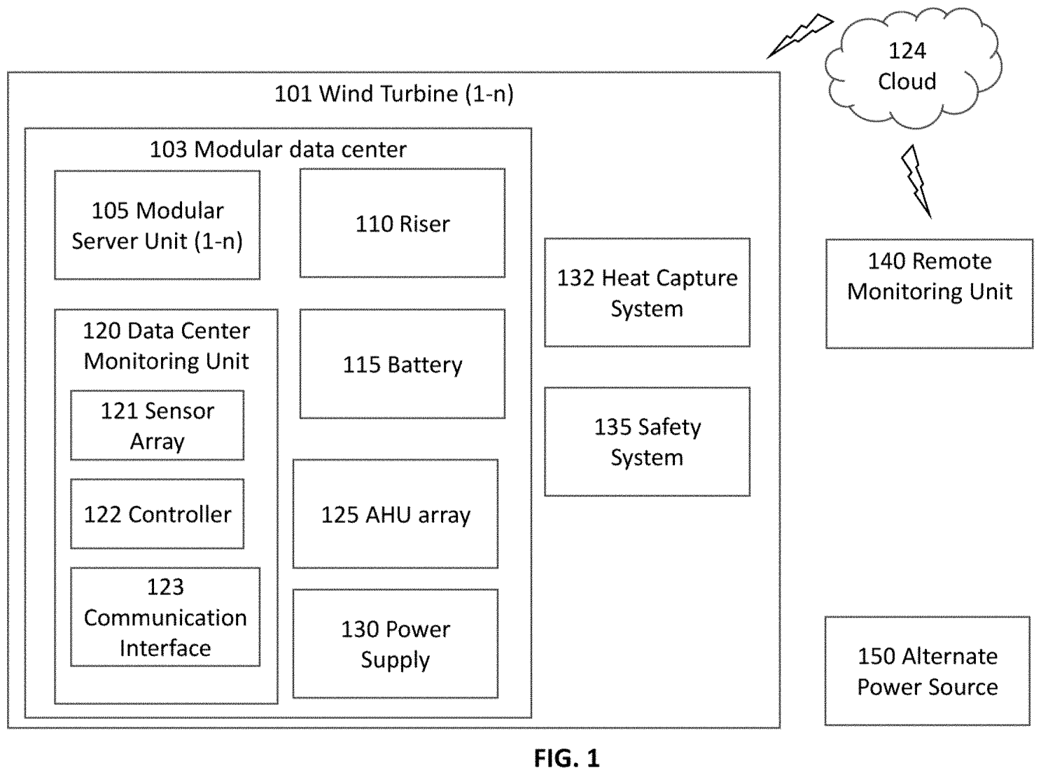

FIG. 1 illustrates an exemplary network environment in which a modular system in which a wind turbine and data center may be implemented. As illustrated, the network environment may include a wind turbine apparatus 101, cloud communication network 124, remote monitoring unit 140, and alternate power source 150. Wind turbine apparatus 101 may communicate using cloud communication network 124 with remote monitoring unit 140 and may be powered using one or more power sources, including main power supply 130 and alternate power source 150.

Wind turbine apparatus 101 may be associated with a wind turbine, which is a rotary device designed to extract energy from the wind. For example, the wind turbine apparatus 101 may be housed in a common housing or interconnected housings with one or more wind turbines. The wind turbine may be configured with a multiple blade arrangement that rotates around a central axis, which may be configured with a vertical axis, horizontal axis, or other axis. The kinetic energy generated by the blades may be captured and converted into electrical power. The wind turbine may be inclusive of a single unit or may include a series of units operating separately or in cooperation with each other. In one embodiment, the wind turbine may be supported by a hollow base or tower, typically conical with a narrowing circumference from ground to top where the blades are mounted. However, any hollow base or tower configuration—such as pyramidal or varying in shape or width—may be used to house the various components discussed herein, including modular data center 103, heat capture system 132, and safety system 135.

Modular data center 103 includes elements to utilize energy from the associated wind turbine to power modular server units 105, mechanical, electrical, plumbing (MEP) risers 110, battery 115, data center monitoring unit 120 (which further includes sensor array 121, controller 122, and communication interface 123), AHU array 125, and power supply 130. In some embodiments, heat capture system 132 and safety system 135 may be part of or otherwise associated with modular data center 103.

A modular server unit 105 is a structure that includes the framework and infrastructure to house data center components, such as computing devices or telecommunications and storage systems. Modular server unit 105 includes a server rack structure, designed to accommodate routers, network switches, hubs, servers etc. Modular server unit 105 may be connected to other components of modular data center 103 either through a wired or wireless connection via data center monitoring unit 120. Depending on the size of wind turbine and the specific design of modular data center 103, there may be multiple modular server units 105, which may be oriented in an arrangement to optimize space within the wind turbine housing, either in a horizontal, vertical, or other configuration.

Riser 110 is a set of ducts, pipes, cables, conduits etc. that are oriented in a substantially vertical direction. In one example, riser 110 may be a mechanical, electrical, plumbing, and sprinklers (MEPS) riser. In another example, riser 110 may be a waterline, sanitary line, air shaft, ventilation piping or shaft, electrical power cable or fire safety system. In yet another example, riser 110 may be a telecommunication, data bus, IT conduit, or similar data transfer cable. Riser 110 connects various elements of the network environment of FIG. 1, such as AHU array 125 to power supply 130. Any elements of wind turbine that require mechanical, electrical, or plumbing support may be connected via riser 110.

A battery 115 stores energy generated by wind turbine apparatus 101 that may be used to supply power to modular data center 103. In one embodiment, battery 115 provides some or all power required to supply data center monitoring unit 120, AHU array 125, or to supply both. Battery 115 may be any of a number of available types, including lead-acid, or lithium ion. In one example, a lithium-ion battery pack from Omega may be used. In another example, other alternate battery types such as hydrogen fuel cells, or a solid oxide fuel cell from Bloom Energy may be used. Battery 115 capacity is selected based on the calculated demand for modular server unit 105. In one example, battery 115 capacity is sized at 1.25 times the load from all components in modular data center 103 being supported. In another example, battery 115 capacity is sized around or about 1.25 to 1.5 times the load from all components in modular data center 103 being supported. In some embodiments, battery 115 is an uninterrupted power source (UPS). In certain embodiments, battery 115 may be omitted.

A data center monitoring unit 120 houses the components required for detecting conditions in the area of modular server unit 105, including sensor array 121, controller 122, and communication interface 123. The components of data center monitoring unit 120 may be co-located within wind turbine apparatus 101 or placed separately, as well as connected in a wired or wireless manner. Data center monitoring unit 120 holds data center components, typically in racks, that may consist of, but are not limited to storage devices, firewalls, network routers, computers, telecommunications equipment, application delivery controllers, crypto-mining machines. In some embodiments, the components of data center monitoring unit 120 may not require battery 115.

A sensor array 121 may include at least one and may consist of a plurality of detection or measurement devices configured to collect data (e.g., regarding a surrounding environment). Sensor array 121 may measure and quantify analog inputs and convert them to digital data though some may natively collect and monitor digital data. Sensor array 121 may be any of position sensors (accelerometers, global positioning system, etc.), pressure sensors (manometers, barometers, etc.), temperature sensors (bolometers, thermocouples, thermometers, etc.), force sensors (force transducers), vibration sensors, piezo sensors, fluid property sensors, humidity sensors, strain gauges, photo optic sensors, flow switches, level switches and may further require contact with the item, substance, or material they are measuring or may not require contact. Similarly, some sensors may measure rotary movement, versus linear movement. Non-contacting sensors may additionally include hall effect sensors, capacitive sensors, eddy current sensors, ultrasonic sensors, laser sensors or proximity sensors. Sensor array 121 may additionally include consumable or catalytic chemical reactions including assays. Sensor array 121 may also include imaging sensors (e.g., cameras) or audio input devices (e.g., microphones).

A controller 122 is a device capable of executing instructions (e.g., program code) to perform specific tasks when executed on a processor (e.g., CPU or CPUs). The program code can be stored in one or more computer-readable memory devices. Controller 122 further includes the capability to capture input from a user such as a keyboard, keypad, mouse, remote control, joystick, or any other array of switches, dials, etc. arranged to receive input from a user. Controller 122 may additionally include a touch screen interface, such as a capacitive, resistive, or pressure detecting surface which may or may not be overlayed upon or beneath a screen capable of displaying content to a user.

A communication interface 123 provides a connection between one or more electronic devices 102 or components. A communication interface 123 may have a physical interface to accept a cable connector such as an ethernet cable, optical cable, USB cable, etc. or may provide for a wireless connection. To provide a wireless connection, a communication interface 123 will include an antenna to send and/or receive data via electromagnetic waves. Wireless connections may be established using any communication protocol such as Wi-Fi, Bluetooth, infrared (IR), cellular (3G, 4G, 5G, LTE, etc.), near field communication (NFC), radio frequency identification (RFID), global positioning system (GPS), etc. In some embodiments, a communication interface 123 may utilize light to establish a physical connection, such as using fiberoptic cables or wirelessly via one or more lasers, visible light communication, etc.

A cloud communication network 124 may be inclusive of a network of distributed computational and data storage resources. Cloud communication network 124 may be a public cloud, such as accessible via the internet, or may be a private cloud, which may be isolated from access via the internet. Similarly, cloud communication network 124 may be widely accessible or access may be restricted via encryption, authentication, etc. In some embodiments, cloud communication network 124 may be maintained by a third party, where resources are provisioned for one or more users and/or organizations. Cloud communication network 124 may be a local, proprietary network (e.g., an intranet or LAN) and/or may be a part of a larger wide-area network (WAN) such as the Internet. The Internet is a broad network of interconnected computers and servers allowing for the transmission and exchange of Internet Protocol (IP) data between users connected through a network service provider. Examples of network service providers are the public switched telephone network, a cable service provider, a provider of digital subscriber line (DSL) services, or a satellite service provider.

An AHU array 125 consists of at least one air handling unit (AHU), used to regulate and circulate air as part of a heating, ventilating, and air-conditioning (HVAC) system. AHU array 125 may contain a blower (or fan) that circulates air, heating or cooling elements, filter racks or chambers, sound attenuators, and dampers. In one embodiment, AHU array 125 provides around or about 50 W of cooling capacity for each 100 W of power demand for components within modular server unit 105. In another embodiment, AHU array 125 is designed to provide sufficient cooling capacity to address thermal output of modular data center 103 ranging from around or about 75-150 kW. In yet another embodiment, AHU array 125 is designed to provide more cooling capacity than required to meet the thermal output of modular data center 103 in order to accommodate future expansion of the system.

A power supply 130 provides electricity required to support operation of data center monitoring unit 120 and AHU array 125. Power input to power supply 130 may be provided via wind turbine apparatus 101 directly, via battery 115 or may be provided via an alternate power source 150. In one example, power supply 130 also provides power to other systems, such as heat capture system 132 and safety system 135. A heat capture system 132 may be used for heat recovery within wind turbine apparatus 101. Heat capture system 132 may be any form of capture, including but not limited to rotary thermal wheels, heat pipes, fixed plate heat exchangers, phase change materials, or combinations of approaches. Energy converted from heat capture system 132 may be routed back to modular data center 103 via power supply 130.

Heat capture system 132 may also be operationally integrated with AHU array 125.

Safety system 135 provides safety controls within wind turbine apparatus 101, such as fire protection, electrical safeguards, physical protection from drops and falls, etc. Safety system 135 may be optionally constructed or may be required by the geography in which wind turbine apparatus 101 is located. In one example, safety system 135 is part of the original construction of wind turbine apparatus 101. In another example, modular data center 103 may provide backup power in an emergency situation to safety system 135 via battery 115.

A remote monitoring unit 140 may be used to monitor conditions of data center monitoring unit 120, and further support activities including but not limited to energy generation reporting, operational parameter control, emergency, and predictive maintenance. Remote monitoring unit 140 may include an operations database to collect and analysis information about the function of wind turbine apparatus 101 and data center monitoring unit 120, a remote computer system controller to read conditions within data center monitoring unit 120 and via human or software driven instructions, implement changes remotely to wind turbine apparatus 101 and/or data center monitoring unit 120, and a remote communication.

An alternate power source 150 provides power in the event that wind turbine apparatus 101 or battery 115 cannot provide sufficient power to modular server units 105. Alternate power source 150 may be fossil-fuel based or alternative fuel-based, including but not limited to coal, nuclear, natural gas, or hydroelectric sources. In another embodiment, alternate power source 150 may be another proximate battery 115 located within a separate proximate wind turbine apparatus 101.

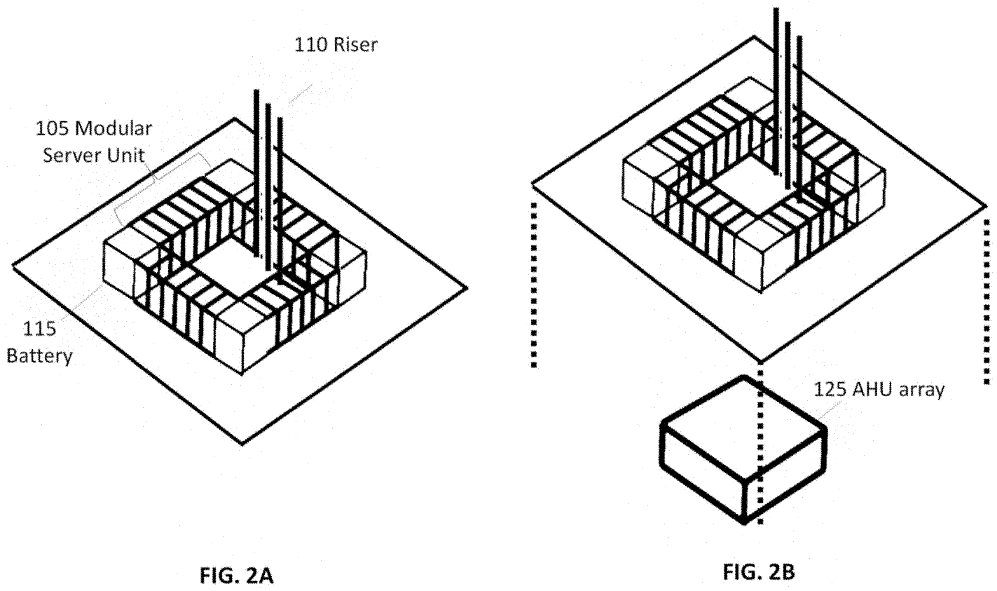

FIGS. 2A-B illustrates exemplary configurations of a modular server unit. Functioning of exemplary modular data centers will now be explained with reference to FIGS. 2A-B. One skilled in the art will appreciate that, for this and other systems, apparatuses, processes, and methods disclosed herein, the elements described may be implemented in differing combinations, arrangements, and orders. Furthermore, the outlined elements and associated steps and operations are only provided as examples, and thus may be optional, combined into fewer steps and operations, or expanded into additional steps and operations without detracting from the essence of the disclosed embodiments.

FIG. 2A shows a possible configuration of modular data center 103. As shown in FIG. 2A, modular data center 103 may include elements to utilize energy generated by a connected wind turbine to power and cool modular server units 105 (and associated data center monitoring units 120). Such a configuration may include modular server unit 105, risers 110, battery 115, data center monitoring unit 120 (not shown), AHU array 125, and power supply 130 (not shown). In some embodiments, heat capture system 132 and safety system 135 (not shown) may also be part of modular data center 103. In one example, one or more risers 110 may be located within the central space created by the arrangement of modular server units 105 and batteries 115. In another example, at least one AHU array 125 is located at a lower elevation compared to the arrangement of modular server units 105 and batteries 115. In another example, a fan may be located at a lower elevation compared to the arrangement of modular server for improved circulation of air.

In a more specific example, AHU array 125 is located at a lower elevation compared to modular server units 105 and batteries 115 and also centrally located in the space created by the arrangement of modular server units 105 and batteries 115, as shown in FIG. 2B. More than one AHU array 125 may be part of modular data center 103 in order to provide sufficient cooling capacity to modular data center 103. Compared to the arrangement of traditional data centers where there are hot and cool aisles exist due to the parallel rows of equipment, the present invention instead provides a hot core in the center of the configuration, and an outer cool perimeter outside of modular server unit 105. In one example, data center components within modular server unit 105 and batteries 115 are oriented with data center components and batteries 115 facing the outer perimeter, and with exhaust or vents facing to the center. The present invention optimizes the cooling process and provides a more efficient design.

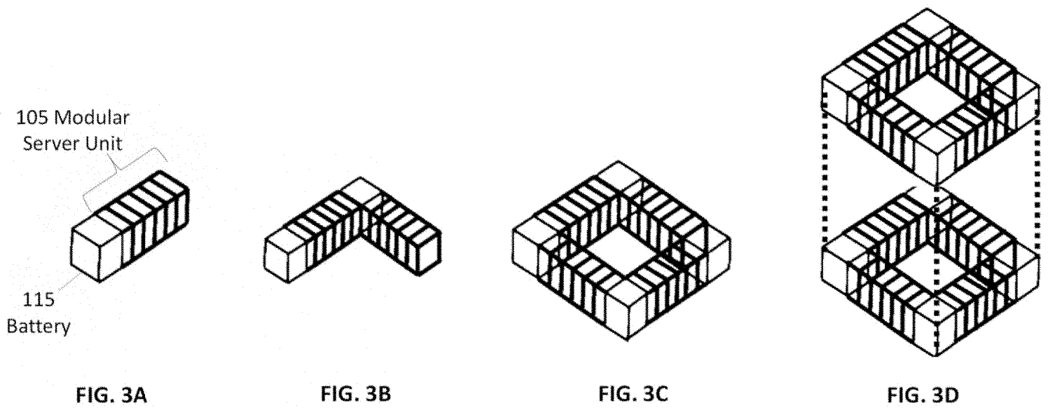

FIGS. 3A-D illustrates exemplary configurations of a modular data center. In one embodiment, battery 115 is located at one end or the other of modular server unit 105 as shown in FIG. 3A. In another embodiment, battery 115 may be disposed within (as shown in FIG. 3B), alongside, on top or underneath modular server unit 105. In one example, a plurality of modular server unit 105 is arranged in a square or rectangular arrangement as shown in FIG. 3C. In another example (not shown), a plurality of modular server unit 105 is arranged in a geometric shape to best fit a wind turbine apparatus 101, which may consist of 3, 4, 5, 6, 7, or 8 or more sides. In another example, a plurality of modular server unit 105 is arranged in a substantially circular arrangement. In another example, multiple groupings of modular server unit 105 are disposed vertically as shown in FIG. 3D. In one example modular server unit 105 is constructed offsite in order to facilitate onsite assembly and reduce the time for installation, compared to traditional onsite construction. Each modular server unit 105 may be designed and configured to fit together with other modular server unit 105 per a specific installation. Each modular server unit 105 may correspond to at least one battery 115 to supply required power for operation. In an alternate embodiment (e.g., for crypto-mining), battery 115 may be omitted.

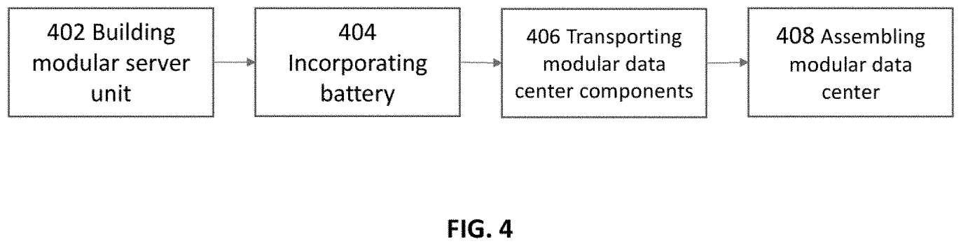

FIG. 4 is a flowchart illustrating an exemplary method of assembling modular data centers. The process begins with step 402, in which the modular server unit 105 is built. Each modular server unit 105 and components thereof may be designed to specification for a particular wind turbine or associated housing, as well as configured so as to ensure that the power demand for the data center components of all total modular server unit 105 together does not exceed the power capacity of the wind turbine of wind turbine apparatus 101 to supply modular data center 103, in addition to the normal power generation activity of the wind turbine. Generally, modular server unit 105 is contemplated to house data center components in a range of 400 kW-850 kW.

In step 404, battery 115 is incorporated into modular server unit 105. Battery 115 capacity is selected based on the calculated demand for modular server unit 105. In one example, battery 115 has a range of around or about 40 to 150 kVA. If modular server unit 105 does not contain a battery, step 404 may be skipped, and method 400 may proceed to step 406.

In step 406, the modular server units 105 with incorporated batteries 115 may be transported to the location of wind turbine apparatus 101. The modular design allows for easier transport compared to traditionally constructed data centers, with lighter duty transport equipment and reduced labor requirements.

In step 408, modular data center 103 may be assembled. Assembly may include physically and electrically connecting all modular server units 105 with batteries 115 incorporated to the wind turbine of wind turbine apparatus 101. The modular server units 105 with batteries 115 incorporated are oriented in the desired configuration to optimize the layout within wind turbine apparatus 101. Note that the modular construction of modular data center 103 allows not only for the benefit of more rapid construction, but similarly allows for more rapid decommissioning or dismantling if needed when data center components require removal, replacement, upgrade, or changing for a different component.

Risers 110 are constructed such that they run substantially vertically within wind turbine apparatus 101, to provide mechanical, electrical, and plumbing support to modular data center 103 and any other systems within wind turbine apparatus 101. In one example, additional administrative functions not directly related to modular data center 103 may be supplied via risers 110, such as heat capture system 132, safety system 135, or other optional services such as lighting, wind turbine control systems, lavatories, etc. AHU array 125 is installed in a position lower than modular data center 103, oriented such that cooling support is delivered in the central vertical space made by the open configuration of modular data center 103. The physical arrangement of modular data center 103 and the position of AHU array 125 optimizes the cooling function within wind turbine apparatus 101. In one example, AHU array 125 may be designed to provide additional or excess cooling capacity to accommodate future expansion needs of modular data center 103.

All data center components to be included in modular data center 103 are placed within modular server unit 105, and physically and electrically connected as needed to other components of wind turbine apparatus 101 and modular data center 103, including the batteries 115, the data center monitoring unit 120, AHU array 125, power supply 130, and optionally physically and electrically connected to heat capture system 132 and safety system 135. Modular data center 103 is also physically and electrically connected as needed to remote monitoring unit 140 and alternate power source 150.

In some embodiments, multiple sets of modular data center 103 may be disposed vertically into wind turbine apparatus 101, and may share physical connections, and electrical connection via risers 110, and optionally power supply 130 and alternate power source 150. An additional advantage of modular data center 103 is the ability to expand or reduce the capacity of the datacenter per module with vertical expansion. In one example modular data center 103 will draw around or about 250 kW of power. In another example, through vertically disposed arrangements of modular data center 103, the total amount of power draw may be around or about 1 MW. Method of constructing a modular data center ends at step 408.

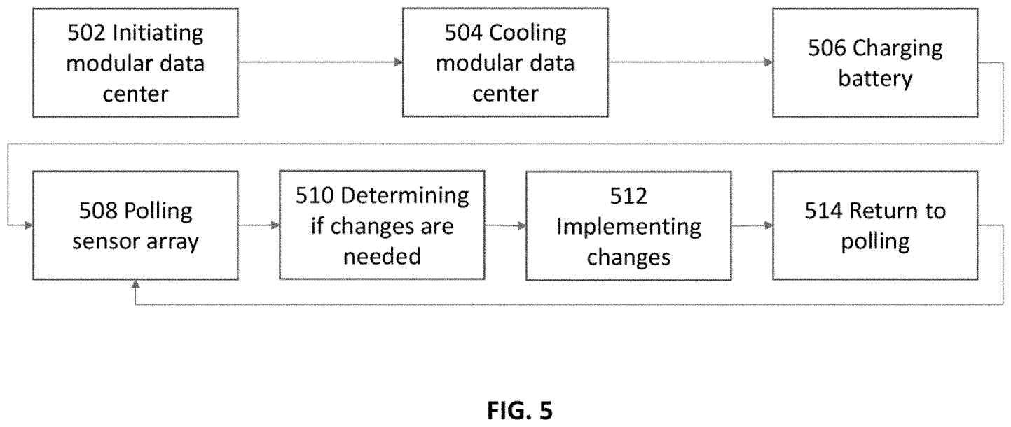

FIG. 5 is a flowchart illustrating an exemplary method of operating modular data centers. The method of FIG. 5 may be embodied as executable instructions in a non-transitory computer readable storage medium including but not limited to a CD, DVD, or non-volatile memory such as a hard drive. The instructions of the storage medium may be executed by a processor (or processors) to cause various hardware components of a computing device hosting or otherwise accessing the storage medium to effectuate the method. The steps identified in FIG. 5 (and the order thereof) are exemplary and may include various alternatives, equivalents, or derivations thereof including but not limited to the order of execution of the same. One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The method of operating modular data center may begin with initiating a modular data center 103 in step 502. Step 502 may include providing modular data center 103 with power from power supply 130, which draws power from wind turbine to supply for the data center components within modular server unit 105, data center monitoring unit 120, and AHU array 125. Power may be provided via power supply 130 and risers 110.

In step 504, cooling of modular data center 103 may be implemented and controlled. AHU array 125, which is electrically connected to power supply 130, provides cooling support to maintain a safe operating temperature for modular data center 103, and particularly the data center components of modular server unit 105.

In step 506, batteries 115 may be charged. Wind turbines associated with the wind turbine apparatus 101 provides power to modular data center 103, and excess power is stored in battery 115. In another example, battery 115 may optionally be charged directly by an alternate power source 150 via power supply 130. If modular data center 103 does not include a battery, step 506 may be skipped, and method 500 may proceed to step 508.

In step 508, sensor array 121 within data center monitoring unit 120 may be polled for sensor data. Sensor array 121 measures conditions within modular data center 103 and in response to polling, sends information wirelessly via communication interface 123 to remote monitoring unit 140 via cloud communication network 124. Conditions monitored may include but are not limited to temperature, pressure, detection of water, smoke or fire, data communication rate, power levels, battery level, battery conditions, weather conditions, etc. Any parameters related to operation of modular data center may be monitored via sensor array 121 and the results transmitted via communication interface 123. In one example, sensor array 121 monitors conditions passively. In another example, a person may initiate sensor array 121 to actively take measurements.

In step 510, it may be determined if changes are needed within operation of modular data center 103. The data collected by sensor array 121 and sent by communication interface 123 is analyzed within remote monitoring unit 140. Through software processes including but not limited to lookup tables, threshold values, decision trees and machine learning, remote monitoring unit 140 determines whether operational parameters are acceptable within modular data center 103. In one example, no changes are needed. In another example, data from sensor array 121 indicates that one or more parameters of modular data center 103 are out of range.

In step 512, changes to operation of modular data center 103 may be implemented. If remote monitoring unit 140 determines that changes to operation of modular data center 103 are required, instructions are sent wirelessly via cloud communication network 124 to communication interface 123 within data center monitoring unit 120. Instructions are interpreted by controller 122 and implemented within modular data center 103. Examples of changes may include shifts in the balance of power provided via battery 115, directly from the wind turbine apparatus 101, or from alternate power source 150. Another example of changes may include increased cooling support from AHU array 125. In another embodiment, remote monitoring unit 140 may provide an alert for an emergency or may provide an alert, notification, or request for routine maintenance to wind turbine apparatus 101 and/or modular data center 103.

In step 514, the method may return to polling sensor array at step 508 or otherwise end. In one example of operation, the wind turbine provides power via a gear system, generator, and controller system to both connected utilities and to modular data center 103, in addition to other loads that may include heat transfer system 132, safety system 135 and other energy demands for lighting, plumbing etc. Via a transfer switch, power may also be provided as needed to modular data center 103 by alternate power sources 150, such as fossil-fuel based or alternative fuel-based power, including but not limited to coal, nuclear, natural gas, or hydroelectric sources. Power flows to modular data center 103 via an emergency bus which is electrically connected in parallel to the critical IT load of modular data center 103 via an uninterrupted power source (UPS), to mechanical loads such as AHU array 125, and other loads such as safety system 135.

The functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

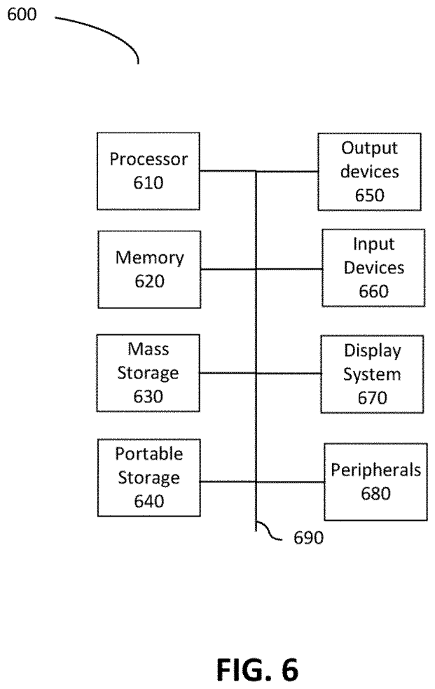

FIG. 6 illustrates an exemplary computing system 600 that may be used to implement an embodiment of the present invention. The computing system 600 of FIG. 6 includes one or more processors 610 and memory 620. Main memory 620 stores, in part, instructions and data for execution by processor 610. Main memory 620 can store the executable code when in operation. The system 600 of FIG. 6 further includes a mass storage device 630, portable storage device(s) 640, output devices 650, user input devices 660, a graphics display 670, and peripheral devices 680.

The components shown in FIG. 6 are depicted as being connected via a single bus 690. However, the components may be connected through one or more data transport means. For example, processor 610 and main memory 620 may be connected via a local microprocessor bus, and the mass storage device 630, peripheral device(s) 680, portable storage device 640, and graphics display 670 may be connected via one or more input/output (I/O) buses.

Mass storage device 630, which may be implemented with a magnetic disk drive or an optical disk drive, is a non-volatile storage device for storing data and instructions for use by processor 610. Mass storage device 630 can store the system software for implementing embodiments of the present invention for purposes of loading that software into main memory 620.

Portable storage device 640 operates in conjunction with a portable non-volatile storage medium, such as a floppy disk, compact disk or Digital video disc, to input and output data and code to and from the computer system 600 of FIG. 6. The system software for implementing embodiments of the present invention may be stored on such a portable medium and input to the computer system 600 via the portable storage device 640.

Input devices 660 provide a portion of a user interface. Input devices 660 may include an alpha-numeric keypad, such as a keyboard, for inputting alpha-numeric and other information, or a pointing device, such as a mouse, a trackball, stylus, or cursor direction keys. Additionally, the system 600 as shown in FIG. 6 includes output devices 650. Examples of suitable output devices include speakers, printers, network interfaces, and monitors.

Graphics display 670 may include a liquid crystal display (LCD) or other suitable display device. Graphics display 670 receives textual and graphical information, and processes the information for output to the display device.

Peripheral device(s) 680 may include any type of computer support device to add additional functionality to the computer system. For example, peripheral device(s) 680 may include a modem or a router.

The components contained in the computer system 600 of FIG. 6 are those typically found in computer systems that may be suitable for use with embodiments of the present invention and are intended to represent a broad category of such computer components that are well known in the art. Thus, the computer system 600 of FIG. 6 can be a personal computer, hand held computing device, telephone, mobile computing device, workstation, server, minicomputer, mainframe computer, or any other computing device. The computer can also include different bus configurations, networked platforms, multi-processor platforms, etc. Various operating systems can be used including Unix, Linux, Windows, Macintosh OS, Palm OS, and other suitable operating systems.

The present invention may be implemented in an application that may be operable using a variety of devices. Non-transitory computer-readable storage media refer to any medium or media that participate in providing instructions to a central processing unit (CPU) for execution. Such media can take many forms, including, but not limited to, non-volatile and volatile media such as optical or magnetic disks and dynamic memory, respectively. Common forms of non-transitory computer-readable media include, for example, a floppy disk, a flexible disk, a hard disk, magnetic tape, any other magnetic medium, a CD-ROM disk, digital video disk (DVD), any other optical medium, RAM, PROM, EPROM, a FLASHEPROM, and any other memory chip or cartridge.

Various forms of transmission media may be involved in carrying one or more sequences of one or more instructions to a CPU for execution. A bus carries the data to system RAM, from which a CPU retrieves and executes the instructions. The instructions received by system RAM can optionally be stored on a fixed disk either before or after execution by a CPU. Various forms of storage may likewise be implemented as well as the necessary network interfaces and network topologies to implement the same.

The foregoing detailed description of the technology has been presented for purposes of illustration and description. It is not intended to be exhaustive or to limit the technology to the precise form disclosed. Many modifications and variations are possible in light of the above teaching. The described embodiments were chosen in order to best explain the principles of the technology, its practical application, and to enable others skilled in the art to utilize the technology in various embodiments and with various modifications as are suited to the particular use contemplated. It is intended that the scope of the technology be defined by the claim.

What is claimed is:

1. A modular data center apparatus, the apparatus comprising:
at least one modular server unit in a selected configuration corresponding to a shape of a wind turbine housing of a wind turbine;
at least one battery configured to store power generated by the wind turbine and to supply the power to the at least one modular server unit; and
an air handling unit array configured to regulate temperature of air in a surrounding environment of the at least one modular server unit.

2. The apparatus of claim 1, further comprising a data center monitoring unit that includes one or more sensors configured to detect and measure one or more conditions in the environment of the at least one modular server unit, wherein the data center monitoring unit is powered by power generated by the wind turbine.

3. The apparatus of claim 2, further comprising a controller that executes instructions to determine to make one or more changes in operation of the at least one modular server unit based on the measurements and to implement the changes in the operation of the at least one modular server unit.

4. The apparatus of claim 1, wherein the at least one modular server unit is located at a center of the configuration.

5. The apparatus of claim 1, wherein the at least one modular server unit and the battery are oriented to face an outer perimeter of the configuration.

6. The apparatus of claim 1, wherein one or more exhausts or vents associated with the air handling unit array face a center of the configuration.

7. The apparatus of claim 1, wherein the air handling unit array is positioned at a lower elevation than the at least one modular server unit within the configuration.

8. The apparatus of claim 1, wherein the at least one modular server unit and the at least one battery are positioned to create a central space within the configuration, and wherein the air handling unit is located in the central space.

9. The apparatus of claim 1, wherein the configuration includes a plurality of interconnected modular server units that includes the at least one modular server unit.

10. The apparatus of claim 9, wherein the plurality of interconnected modular server units includes a plurality of groupings of the modular server units, and wherein at least one of the groupings is disposed vertically to another one of the groupings.

11. The apparatus of claim 1, wherein at least one modular server unit is reconfigurable into a different configuration.

12. The apparatus of claim 1, further comprising a communication interface that communicates over a communication network to receive control instructions from a remote computer.

13. The apparatus of claim 12, wherein the communication interface further provides sensor measurements captured by a data center monitoring unit over the communication network to the remote computer.

14. The apparatus of claim 12, wherein the remote computer is associated with a remote modular data center.

15. The apparatus of claim 1, wherein the at least one battery is removable or replaceable.

16. The apparatus of claim 1, wherein a power demand of the at least one modular server unit is in a range of 250 kW to 1.4 MW.

17. The apparatus of claim 1, wherein a power demand of the at least one modular server unit is in a range of 400 kW-850 kW.

18. The apparatus of claim 1, wherein capacity of the at least one battery is between 1.25-1.5 times a power demand of the at least one modular server unit.

19. The apparatus of claim 1, wherein the at least one modular server unit houses at least one of storage devices, firewalls, network routers, application delivery controllers, and crypto-mining machines.

20. A method of operating a modular data center situated in a wind turbine, the method comprising:
storing power generated by the wind turbine in at least one battery;
supplying the stored power from the at least one battery to at least one modular server unit in a selected configuration corresponding to a shape of a wind turbine housing of the wind turbine; and
regulating temperature of air in a surrounding environment of the at least one modular server unit, wherein the air temperature is regulated by an air handling unit array.

21. The method of claim 20, wherein regulating the air temperature includes cooling the air, and wherein the air handling unit array is powered by power generated by the wind turbine.

22. The method of claim 20, further comprising polling a sensor array of a data center monitoring unit for measurements of one or more conditions in the environment of the at least one modular server unit.

23. The method of claim 22, further comprising determining to make one or more changes in operation of the at least one modular server unit based on the measurements, and implementing the changes in the operation of the at least one modular server unit.

24. The method of claim 23, wherein implementing the changes includes changing use of power from one or more of the wind turbine, the at least one battery, and another alternate power source.

25. The method of claim 23, wherein implementing the changes includes sending a notification to a designated maintenance support device when the measurements exceed a predetermined range.

26. A method of installing a modular data center in a wind turbine, the method comprising:
assembling one or more modular server units into a selected configuration corresponding to a shape of a wind turbine housing of the wind turbine;
incorporating at least one battery for each modular server unit in the configuration by establishing at least one physical or electrical connection between the modular server units and the at least one battery;
connecting the at least one battery to the wind turbine, wherein power generated by the wind turbine is stored in the at least one battery; and
initiating operation of the modular server units using power stored in the at least one battery.
